(19) United States
(12) Patent Application Publication
(10) Pub. No.: US 2024/0107689 A1
(43) Pub. Date: Mar. 28, 2024

(54) ELECTRONIC DEVICE WITH INTERNAL LIGHT CURING

(71) Applicant: Bose Corporation, Framingham, MA (US)

(72) Inventors: Alexander Irwin, Belmont, MA (US); Thomas David Chambers, Bellingham, MA (US); Todd William MacFadden, Brookline, MA (US); Ricardo Federico Carreras, Southborough, MA (US)

(21) Appl. No.: 18/370,965

(22) Filed: Sep. 21, 2023

Related U.S. Application Data
(60) Provisional application No. 63/409,912, filed on Sep. 26, 2022.

(51) Int. Cl. H05K 5/02; C09J 5/06; H04R 1/02

(52) U.S. Cl. CPC H05K 5/0217; C09J 5/06; H04R 1/02; C09J 2301/416; H04R 2201/029

(57) ABSTRACT

Various implementations include electronic devices with internal joints cured by a light source. In a particular implementation, an electronic device includes: a casing defining an enclosure; a joint between components in the electronic device; a light curable adhesive bonding the components at the joint; and at least one light source internal to the casing and configured to output light for at least partially curing the light curable adhesive in the casing.

### PRIORITY CLAIM

This application claims priority to U.S. Provisional Patent Application 63/409,912, filed Sep. 26, 2022, the entire contents of which are incorporated by reference.

### TECHNICAL FIELD

This disclosure generally relates to joints in electronic devices. More particularly, the disclosure relates to cured joints in electronic devices.

### BACKGROUND

Light curable adhesives can provide various benefits in bonding electronic device components. However, certain conventional electronic devices do not allow for curing of such adhesives and consequently have joints with vulnerable or otherwise undesirable adhesive bonds.

### SUMMARY

All examples and features mentioned below can be combined in any technically possible way.

Various implementations include electronic devices with internally cured joints, as well as methods of curing such joints.

In some particular aspects, an electronic device includes: a casing defining an enclosure; a joint between components in the electronic device; a light curable adhesive bonding the components at the joint; and at least one light source internal to the casing and configured to output light for at least partially curing the light curable adhesive in the casing.

In other particular aspects, an electronic device includes: a casing defining an enclosure; a joint between components in the electronic device; a light curable adhesive bonding the components at the joint; and a light pipe permitting a light source external to the casing to pass light therethrough for curing the light curable adhesive within the casing.

In further particular aspects, an electronic device includes: a casing defining an enclosure; a joint between components in the electronic device; a light curable adhesive bonding the components at the joint; and an opening in the casing sized to accommodate a light probe for outputting light to at least partially cure the light curable adhesive within the casing.

In additional particular aspects, a method includes: applying a light curable adhesive to a joint in an electronic device, assembling the electronic device, and actuating a light source to provide light with sufficient intensity to at least partially cure the light curable adhesive within the electronic device.

Implementations may include one of the following features, or any combination thereof.

In certain aspects, the light curable adhesive is a ultra-violet (UV) curable adhesive and the light source is a UV light source.

In some cases, the light curing partially cures the light curable adhesive (e.g., fixture cure), where a full cure is finished by humidity exposure over time.

In some cases, the electronic device further comprises a light pipe proximate to the at least one light source for distributing the light to cure the light curable adhesive. In some cases, the light pipe routes light from inside the device to another location within the casing.

In certain aspects, the casing is substantially opaque.

In some cases, after the casing is assembled, the light curable adhesive is only exposed to light from the at least one light source. In various implementations, the joint is not visible to the naked eye (e.g., a user) from the exterior of the enclosure. In certain examples, the casing obstructs entry of light to the joint.

In particular implementations, the electronic device further includes: a printed circuit board (PCB) in the enclosure, wherein the at least one light source is coupled with the PCB.

In certain aspects, the at least one light source includes a light emitting diode (LED).

In some cases, the electronic device further includes a reflective mask on the PCB for diffusing the light.

In particular aspects, the LED is mounted directly to the PCB. In additional aspects, the LED is mounted on a side of the PCB, or in a through-hole in the PCB. In certain examples, the PCB is at least partially transparent to permit the UV light to pass therethrough.

In certain aspects, the LED includes a multi-directional LED.

In some implementations, the PCB is configured to diffuse the light from the LED during curing of the light curable adhesive.

In certain cases, the electronic device further includes a controller coupled with the at least one light source for selectively controlling the output of light for curing the light curable adhesive.

In some aspects, the at least one light source comprises a multi-wavelength light source, and wherein the controller is configured to: actuate output of a first wavelength of light from the at least one light source for curing the light curable adhesive; and actuate output of a second wavelength of light from the at least one light source for providing a light indicator at the electronic device, wherein the first wavelength comprises a portion of the UV spectrum.

In certain examples, the multi-wavelength light source includes a multi-wavelength LED. In some examples, the first wavelength of light is driven at a first voltage, and the second wavelength of light is driven at a second voltage. In further examples, the first wavelength includes a portion of the UV spectrum such as approximately 200 nm to approximately 450 nm. In some examples, the first wavelength includes a plurality of sub-wavelengths, e.g., approximately 200-250 nm, 250-300 nm, 300-350 nm, 350-400 nm, 400-450 nm.

In certain cases, the controller is configured to output the first wavelength of light during assembly of the electronic device and output the second wavelength of light after assembly of the electronic device is complete.

In particular implementations, the at least one light source comprises a multi-direction light source, and wherein the controller is configured to: actuate output of light from the at least one light source in a first direction for curing the light curable adhesive; and actuate output of light from the at least one light source in a second direction for providing a light indicator at the electronic device. In particular examples, the multi-direction light source includes a multi-direction LED.

In some aspects, the electronic device further includes an at least partially reflective coating within the enclosure for diffusing the light. In some examples, the coating includes a reflective (e.g., white) solder mask on a PCB, or another reflective coating along any portion of the inner surface of the casing and/or enclosure.

In certain cases, the at least one light source is powered by a device external to the casing.

In particular aspects, the device external to the casing is configured to power the at least one light source by one or more of: inductive coupling, radio-frequency (RF) communication, trans-enclosure capacitive coupling, or hard-wired power extending through the casing.

In certain examples, inductive coupling is achieved with ferrite couplings located proximate to (e.g., adjacent to) LED(s), RF communication is achieved with a transmitter/receiver coupled with the LED(s), hard-wired power is achieved with mechanical/electrical leads connecting LED(s) with external power source(s). In further examples, externally powered light source(s) such as LEDs can be located at one or more locations in the enclosure, and not necessarily connected with and/or proximate to the PCB.

In some implementations, the light curable adhesive is additionally cured with humidity exposure. The humidity cure can fully cure the adhesive in some examples.

In some cases, the casing is an outermost casing of the electronic device.

In particular implementations, an audio device includes the electronic device.

In some aspects, the audio device comprises an earbud or an earphone.

In certain cases, the audio device comprises a speaker system.

In some aspects, a storage case includes the electronic device. In further cases, the storage case includes a charging case.

In particular implementations, the light source is powered externally relative to the casing.

In some cases, the light pipe is at least one of shaped or sized to direct the light from the light source to the light curable adhesive.

In particular cases, the light probe is coupled with a power source external to the electronic device.

In certain aspects, the light probe comprises a UV light cable.

In particular implementation, the opening comprises a nozzle opening in the casing. In certain of these cases, the opening is a nozzle in an earbud.

In some cases, an earbud includes: a transducer for providing an audio output; a nozzle acoustically coupled with the transducer and positioned to provide the audio output to an ear of a user; and a microphone positioned in the nozzle, wherein the joint includes a mounting joint for the microphone and the casing, and wherein the opening is located in the nozzle to permit the light to cure the light curable adhesive at the joint.

In certain cases, a method further includes selectively actuating the light source for: curing the light UV curable adhesive, and providing a light indicator at the electronic device.

Two or more features described in this disclosure, including those described in this summary section, may be combined to form implementations not specifically described herein.

The details of one or more implementations are set forth in the accompanying drawings and the description below. Other features, objects and benefits will be apparent from the description and drawings, and from the claims.

### BRIEF DESCRIPTION OF THE DRAWINGS

FIG. 1 is a cross-section of an electronic device according to various implementations.

FIG. 2 is a cross-section of an example electronic device according to various implementations.

FIG. 3 is a cross-section of another example electronic device according to various implementations.

FIG. 4 is a perspective view of a section of the electronic device of FIG. 3.

FIG. 5 is a close-up perspective of a portion of the electronic device in FIGS. 3 and 4.

FIG. 6 is a cross-section of another example electronic device according to various implementations.

FIG. 7 is a flow diagram illustrating processes in a method according to various implementations.

It is noted that the drawings of the various implementations are not necessarily to scale. The drawings are intended to depict only typical aspects of the disclosure, and therefore should not be considered as limiting the scope of the implementations. In the drawings, like numbering represents like elements between the drawings.

### DETAILED DESCRIPTION

This disclosure is based, at least in part, on the realization that a light curable adhesive can be beneficially deployed in a joint that is internal to an electronic device casing, for example, to enhance bonding of components. In particular implementations, electronic devices and methods are described that beneficially utilize a light curable adhesive to bond an internal (e.g., visibly obstructed and/or light obstructed) joint. In certain cases, during manufacture and/or assembly of the electronic device, the light curable adhesive is cured after the joint is assembled. In a particular case, the light source is ultra-violet (UV) light and the adhesive a UV-curable adhesive. In various particular cases, the light cure applied to the light curable adhesive at least partially cures the adhesive, for example, as a fixture cure. Final curing can occur with exposure to humidity (e.g., ambient environmental conditions) over time. In contrast to conventional electronic devices, the electronic devices described herein can benefit from stronger joints between components, simplified manufacturing and/or assembly processes in forming such joints.

Commonly labeled components in the FIGURES are considered to be substantially equivalent components for the purposes of illustration, and redundant discussion of those components is omitted for clarity. Numerical ranges and values described according to various implementations are merely examples of such ranges and values, and are not intended to be limiting of those implementations. In some cases, the term “approximately” is used to modify values, and in these cases, can refer to that value+/−a margin of error, such as a measurement error, which may range from up to 1-5 percent.

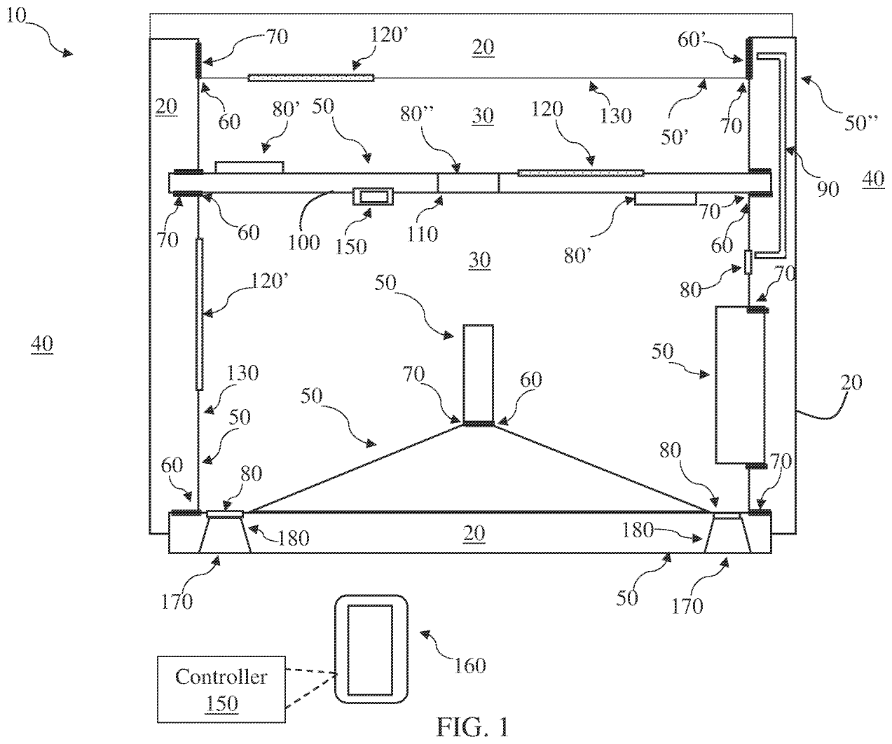

FIG. 1 is a cross-section of a portion of an electronic device 10 according to various embodiments. As described herein, the electronic device 10 can embody one of a variety of electronic devices, i.e., devices with one or more electronic components therein. In particular cases, the electronic devices described herein include components such as a power source (e.g., battery, power connector), a controller (e.g., processor(s), control circuit, printed circuit board, digital signal processor(s), etc.), an interface (e.g., a visual, haptic and/or audio interface), displays (e.g., screens or multi-purpose interfaces) and/or audio components (e.g., electro-acoustic transducer(s), microphones, etc.). The electronic device 10 depicted in FIG. 1 includes numerous features (e.g., internal joints and associated adhesives for bonding those joints) that may not be present on a single electronic device, and are merely illustrative of certain aspects of the disclosure.

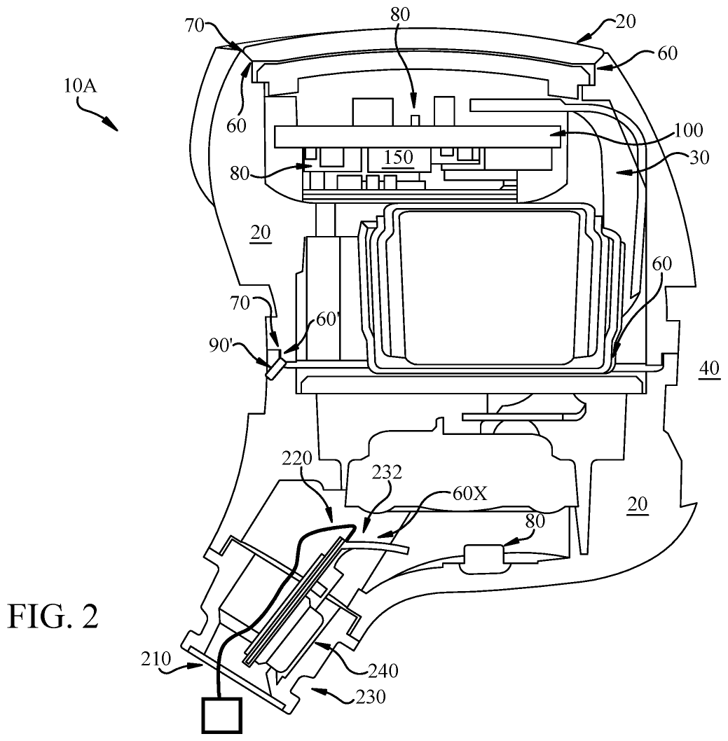

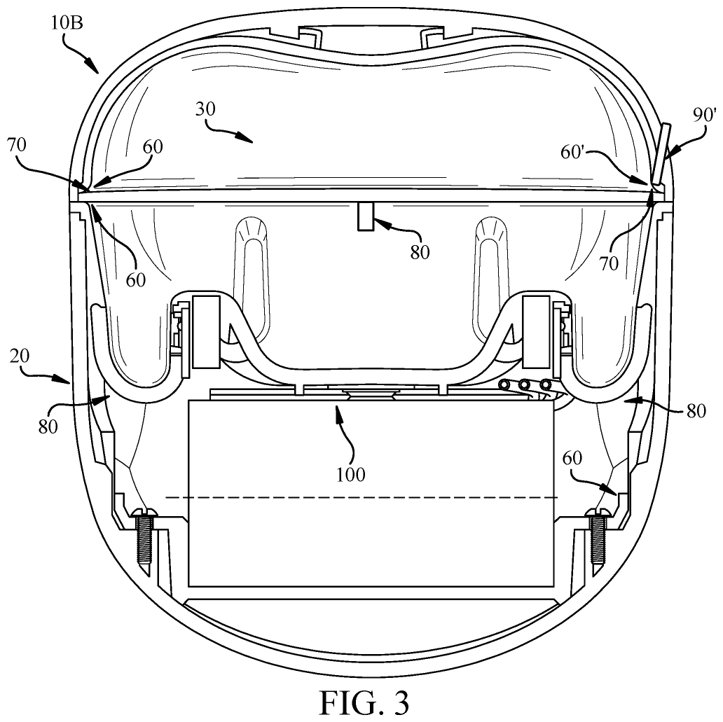

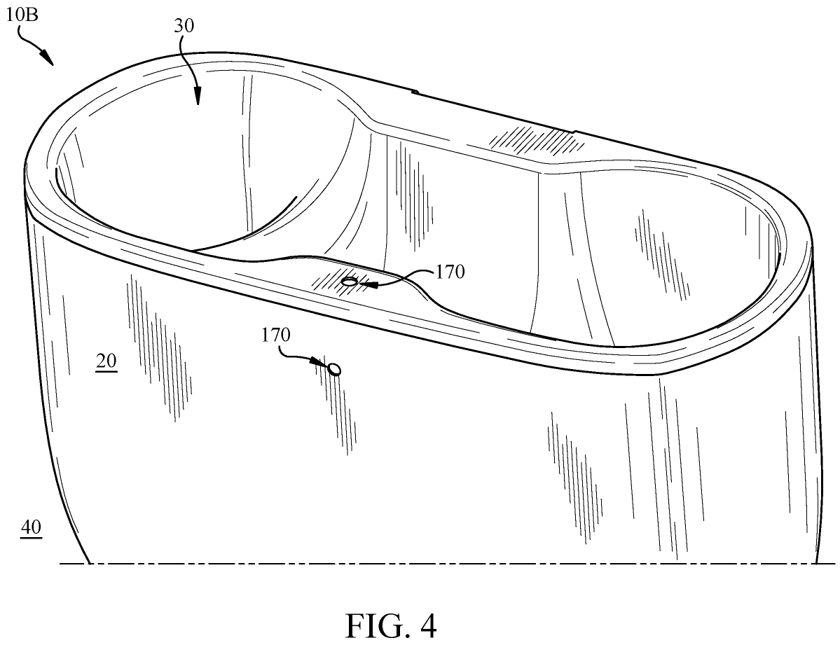

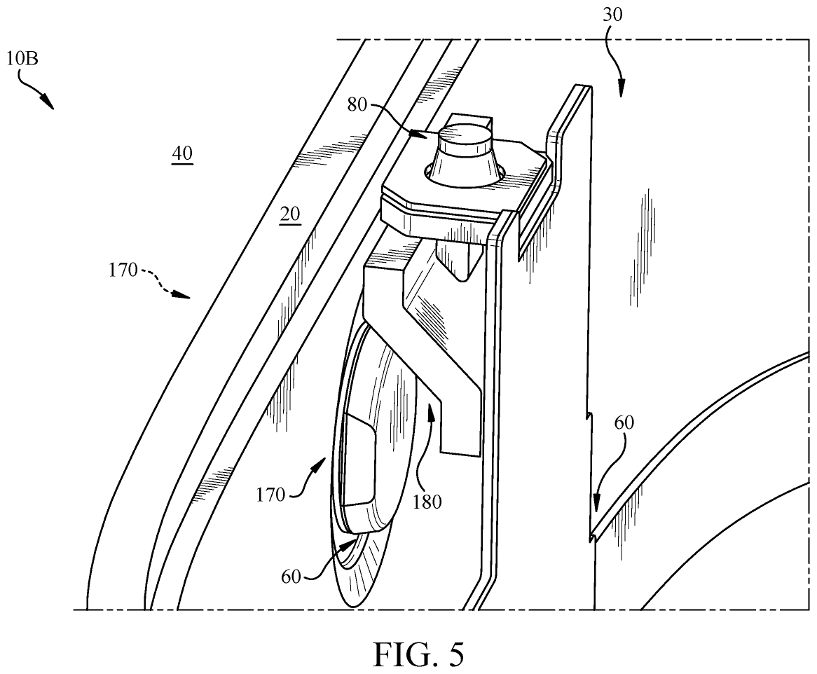

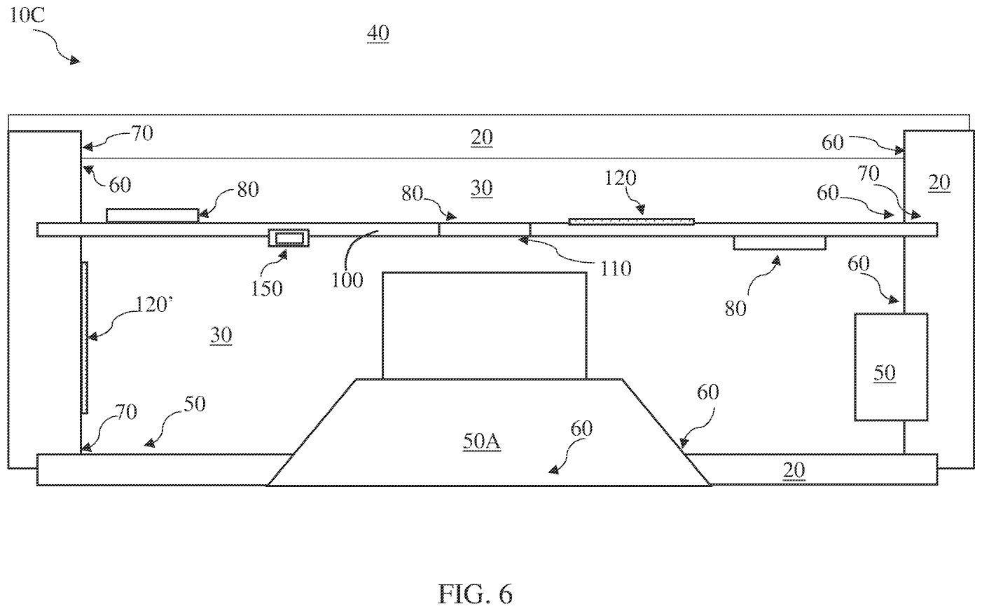

In certain examples, such as illustrated in FIG. 2, the electronic device 10 includes an audio device 10A (e.g., a wearable audio device such as an earphone, headphone, audio glasses). In one example, the audio device 10A in FIG. 2 is an earphone such as an earbud. In further examples, such as illustrated in FIGS. 3-5, the electronic device includes a case 10B (e.g., a storage and/or charging case for another electronic device). In one example, the case 10B includes a storage and/or charging case for an earphone such as an earbud. In additional examples, the electronic device 10 includes a loudspeaker (e.g., portable, permanent, and/or semi-permanent loudspeaker), such as illustrated in the loudspeaker 10C in FIG. 6. In one example, the loudspeaker 10C includes a portable loudspeaker or a soundbar. Further implementations of electronic device can include (but are not limited to): computing devices (e.g., desktop computers, laptop computers, tablet computing devices), communication devices (e.g., phones, smartphones, smart watches, smart wearable devices), navigation devices (e.g., GPS devices), health-related electronic devices (e.g., wearable health monitors), display devices (e.g., monitors, televisions), interfaces (e.g., touch interfaces, visual interfaces), etc. Further, any electronic device including joints that are obstructed from light during manufacture and/or assembly can benefit from the various disclosed implementations.

Returning to the description of electronic device 10 in FIG. 1, with continuing relevance to the electronic devices noted herein (e.g., electronic devices 10A-10C in FIGS. 2-6), the device 10 can include a casing 20 that defines an enclosure 30. In certain examples, the casing 20 is an outermost casing of the electronic device 10. For example, the outer surface of the casing 20 is the surface of the electronic device 10 that is visible to the consumer in a manufactured product (not accounting for any potential surface coatings, decals, etching, etc.). In various implementations, the enclosure 30 is a space protected at least in part from the external environment (e.g., ambient environment) 40 by the casing 30. In certain implementations, the casing 20 provides ingress resistance for components 50 in the enclosure 30, e.g., ingress protection from the environment 40. In some examples, the casing 20 provides ingress resistance as measured by an ingress protection (IP) rating on the IP scale (as defined by International Protection Marking standards set forth by the International Electrotechnical Commission (IEC)). Within the enclosure 30 or at least internal to the outer surface of the casing 20, is at least one joint 60 between components 50 (e.g., between adjacent components, or between sub-components in a component). It is understood that portions of the casing 20 can be considered components 50, at which joints 60 are formed, and which can be internal joints 60 according to various implementations. The joint 60 is formed by a light curable adhesive (or simply, adhesive) 70 between the components. In the example shown in FIG. 1, a plurality of joints 60 are illustrated between adjacent components 50. In particular implementations, e.g., as shown in FIG. 1, the electronic device 10 also includes at least one light source 80 internal to the casing 20 (i.e., internal to the outer surface of the casing 20) that is configured to output light for at least partially curing the adhesive 70 within the casing 20.

In certain aspects, the adhesive 70 is an ultra-violet (UV) curable adhesive and the light source 80 is a UV light source. For example, the adhesive 70 can include a light-curable adhesive such as a free radical light cure adhesive, an anionic light cure adhesive, or a cationic light cure adhesive. Examples of such adhesives are provided by Henkel Corporation (Rocky Hill, Connecticut, USA). The adhesive 70 can be cured in two stages: i) a light-based cure by the light source(s) 80; and ii) a humidity-based cure by exposure to the environment 40 over time. In various implementations, the light-based cure performs a fixture cure, while the humidity-based cure is the “final” curing process for the joint 60. The fixture cure can be strong enough to inhibit separation of components 50, e.g., without the need for a separate fixture to hold those components together. In other terms, the fixture cure provides sufficient strength to overcome internal stresses or loads on the joint 60 to hold the components 50 together, while also being strong enough to withstand subsequent manufacturing steps without negatively impacting the stability of the joint 60. The fixture cure can be achieved within several minutes, e.g., three, four, five, six, or seven minutes. In a particular case, the fixture cure can be achieved in two or three minutes, and in more particular cases, in seconds (e.g., 5 seconds to 30 seconds). In contrast, curing the joint 60 solely with humidity may take dozens of hours, e.g., up to 72 hours. That is, without the light-based cure, the adhesive 70 would cure by exposure to the natural humidity that is allowed to ingress to the joint 60 via the casing 20. However, as described herein, the light-based cure significantly enhances the strength of the joint 60 between the components 50 as compared with a humidity-based cure alone, and can also increase the speed with which the joint 60 is bonded.

Looking at FIG. 1, after assembly of the joint 60, and prior to the curing of the adhesive 70, the joint 60 is not visible from an exterior of the casing 20 (i.e., from the outside environment 40). In various implementations, the casing 20 is opaque, such that little or no light passes therethrough from the environment 40 to the joint 60. In other words, the joint 60 is substantially shielded from light in environment 40 once the components 50 are assembled using the adhesive 70. In a particular example, after the casing 20 is assembled, the adhesive 70 is only exposed to light from the light source 80.

In some implementations, a light source 80 internal to the outer surface of the casing 20 is proximate to the joint 60 such that the joint 60 (and the adhesive 70) can be exposed to light during assembly and/or manufacture. In additional implementations, the adhesive 70 at the joint 60 is not directly exposed to the light source 80 internal to the casing 20. In these cases, as illustrated in the upper right-hand portion of FIG. 1, a joint 60′ including adhesive 70 between components 50′ and 50″ is exposed to the light source 80 via a light pipe 90 that is proximate to a light source 80 and coupled (e.g., optically coupled) with the space around the joint 60′ for distributing the light to cure the adhesive 70 at joint 60′. In such cases, the light pipe 90 is configured to route light from the light source 80 to another location within the casing 20.

In a particular example, as illustrated in one location in FIG. 1, the light source 80 is coupled with a circuit board such as a printed circuit board (PCB) 100 in the enclosure 30. The light source 80 can include any light that is capable of outputting visible light (approximately 400-480 nanometers (nm)) and/or UV light (UVA of approximately 315-400 nm). In some cases, the light source 80 is capable of outputting light in a wavelength range of approximately 315 to approximately 480 nm (e.g., the spectrum of UV light to visible light). In some cases, the light source 80 is also configured to output light in wavelengths below UVA, e.g., in the UVB or UVC spectrum such as between 200 nm and 315 nm. In these and other examples, the light source 80 can include a light emitting diode (LED). In certain examples, the light source 80 includes an LED such as a multi-direction LED, for example, an LED that can emit light in more than one direction. In a particular example, the light source 80 (e.g., LED) is mounted directly to the PCB 100. For example, one light source 80′ is shown mounted on a first side of the PCB 100, while a second light source 80″ is shown mounted in a through-hole 110 in the PCB 100. In some cases, the PCB 100 is at least partially transparent to enable light to pass therethrough. In certain examples, such as where the PCB 100 is at least partially transparent, and/or where the PCB 100 includes a through-hole 110 with the light source 80″ mounted therein, the PCB 100 can be configured to diffuse light from the light source (e.g., LED) during curing of the adhesive 70.

In certain cases, the PCB 100 includes an at least partially reflective coating 120 for diffusing light from the light source 80. Examples of reflective coating 120 can include a solder mask or coating on a portion of the PCB 100 (e.g., a white coating to reflect light). In further implementations, the coating 120 can be applied to any portion of the inner surface 130 of the casing 20, e.g., such that light within the enclosure 30 can be reflected from the coating 120. An example application of a coating 120′ along the inner surface 130 of the casing is illustrated along the left-hand portion of the casing 20 in FIG. 1.

In particular cases, a controller 150 is coupled with the light source 80 for selectively controlling the output of the light for curing the adhesive 70 in one or more locations in the device 10. In one example, the controller 150 is located on the PCB 100, or is coupled with the PCB 100 (e.g., via hard-wired connection or wireless connection). In additional examples, the controller 150 is located on another circuit and/or wiring platform, e.g., along an inner surface 130 of the casing 20 (or along any surface of a component 50 in the casing 20). For example, a printed circuit and/or a laser direct structuring (LDS) formed circuit can be located on the inner surface 130 of the casing 20 and coupled with one or more light source(s) 80, e.g., for providing power and/or control functions described herein. In such examples, the printed circuit and/or LDS formed circuit can be located proximate a light source 80, e.g., adjacent to a light source 80 along an inner surface 130 of the casing 20 and/or along a surface of a component 50. In another implementation, the controller 150 is part of an external device 160 (FIG. 1) that controls operation of the light source 80 from a location external to the casing 20. In some cases, the external device 160 can include an external power source and/or an external control source for the light source 80, and can be coupled with the light source via wireless and/or hard-wired means. In a particular example, the external device 160 is configured to power the at least one light source 80 by one or more of: inductive coupling, radio-frequency (RF) communication, trans-enclosure capacitive coupling, or hard-wired power extending through the casing 20 (e.g., through a conduit in the casing 20). In certain examples, inductive coupling is achieved with ferrite couplings located proximate to (and, in some cases, adjacent to) light source(s) 80 (e.g., LED), RF communication is achieved with a transmitter/receiver coupled with the light source(s) 80 and external device 160, hard-wired power is achieved with mechanical/electrical leads connecting light source(s) 80 with external device 160. In further examples, as noted herein, externally powered light source(s) 80 such as LEDs can be located at one or more locations in the enclosure 30, and not necessarily connected with and/or proximate to the PCB 100. Further, the electronic device 10 can include a plurality of PCBs 100 (not shown) for controlling one or more functions of the device 10. Even further, as noted herein, the light source(s) 80 can be powered and/or controlled by electronics (and in some cases, supporting wiring) that are located along an inner surface 130 of the casing 20 (or along any surface of a component 50 in the casing 20). For example, a printed circuit and/or a LDS formed circuit can be located on the inner surface 130 of the casing and coupled with one or more light source(s) 80, e.g., for providing power and/or control functions described herein.

In a particular example, the controller 150 (either within the enclosure 30 or external to the enclosure 30) is configured to selectively control output of light from the light source 80 to at least partially cure the adhesive 70. In some aspects, the light source 80 includes a multi-wavelength light source, the controller 150 is configured to: I) actuate output of a first wavelength of light from the light source 80 for curing the adhesive 70; and II) actuate output of a second wavelength of light from the light source 80 for providing a light indicator at the electronic device 10. For example, the light source 80 can be configured to provide a light indicator 170 during use of the electronic device 10, e.g., via a conduit 180 (e.g., in FIGS. 1, 4 and 5) to the outer surface of the casing 20. In certain examples, the conduit 180 includes a lens. In some cases, the light indicator 170 provides visible feedback to a user that the device 10 is powered on, in use, charging, connected to another device (e.g., via Bluetooth), and/or any other suitable electronic device indicator. In such cases, the light source 80 is configured for use in two ways: as a light curing source inside the device 10, and as a light indicator for end-user operation of the device 10. In such cases where the light source 80 has multi-wavelength capability, the controller 150 can be configured to control which wavelength(s) are used for each mode of operation. In such examples, the first (curing) wavelength can include a portion of the UV spectrum. In certain examples, the multi-wavelength light source includes a multi-wavelength LED. In some examples, the first wavelength of light is driven at a first voltage, and the second wavelength of light is driven at a second voltage. In further examples, the first wavelength includes a portion of the UV spectrum such as approximately 200 nm to approximately 450 nm. In some examples, the first wavelength includes a plurality of sub-wavelengths, e.g., approximately 200-250 nm, approximately 250-300 nm, approximately 300-350 nm, approximately 350-400 nm, approximately 400-450 nm.

In certain cases, e.g., where multi-wavelength operation is used, the controller 150 is configured to cause the light source 80 to output the first wavelength of light during assembly of the electronic device 10 and output the second wavelength of light after assembly of the electronic device 10 is complete (e.g., for device testing and/or for end user operation).

In further examples, the light source 80 includes a multi-direction light source, and the controller 150 is configured to: a) actuate output of light from the light source 80 in a first direction for curing the adhesive 70 (e.g., internally to the enclosure 30, such as toward joint(s) 60); and b) actuate output of light from the light source 80 in a second direction for providing a light indicator at the electronic device 10 (e.g., externally via the conduit 180).

Additional implementations can include one or more light pipes passing through at least a portion of the casing 20, the light pipe permitting a light source external to the casing 20 to pass light therethrough for curing the adhesive 70 within the casing 20 (e.g., at joint(s) 60). In some examples, as illustrated in the device 10A in FIG. 2 and device 10B in FIG. 3, an externally connected light pipe 90′ can be positioned to allow a light source external to the casing 20 to pass light therethrough for curing the adhesive at a joint 60′. In these cases, light pipe 90′ is shaped and/or sized to direct the external light through the casing 20 to the joint 60′. For example, the light pipe 90′ can have a tapered shape (from outer surface of casing 20 to inner surface of casing 20) and/or a difference in size between an inlet (at outer surface) and an outlet (at inner surface) that intensifies the light from the outside light source as it reaches the joint 60′. In some cases, the light pipe 90′ has an outlet that is adjacent to the joint 60′, and in particular cases, directed to the joint 60′ such that light beams passing through the light pipe 90′ are directed to the adhesive 70 at joint 60′. In various implementations, the outside (or, external) light source can include a UV light source, and can be powered by a source external to the electronic device 10 (e.g., via hard-wired power and/or battery power). While certain examples of light pipe shape, size and location are described relative to electronic devices herein, the disclosed implementations enable various light pipe shapes, sizes, and/or locations for beneficially introducing external light to particular joints inside an electronic device casing. In various implementations, use of an outside (or, external) light source can reduce or eliminate the need for additional parts (and space) within the device 10 (e.g., light source), along with their associated costs, when compared with a light source internal to the device 10. Additionally, the use of an outside light source can obviate the need for storing additional control routine(s) in memory at the device 10, when compared with a light source internal to device 10 that is internally controlled.

In certain additional implementations, one or more joints can be bonded with an adhesive using an external light probe. For example, the casing in an electronic device (e.g., electronic device 10) can include an opening that is sized to accommodate a light probe for outputting light to at least partially cure an adhesive at an internal joint. FIG. 2 illustrates one example of an electronic device 10A such as an earbud that has an opening 210 sized to accommodate a light probe 220. The light probe 220 can be configured to output light (e.g., at a distal end 232 thereof) for at least partially curing the adhesive 70 at joint 60″. In some examples, the light probe 220 includes a UV light probe. In certain cases, for example where the electronic device 10 is an earbud with a nozzle 230, the opening 210 in the nozzle 230 can be sized to accommodate the light probe 220 for curing the adhesive 70 at joint 60″ and/or at additional joints in the region of the nozzle 230. In a particular example, the nozzle 230 can include a microphone 240 (and additional components such as mesh or other cover for the microphone), and one or more joints (e.g., joint 60X) can benefit from adhesive 70 that is cured via a light probe 220 through the opening 210. The example of a nozzle 230 in an audio device such as an earbud is only one example of an electronic device 10 opening that benefit from use of a light probe to cure a joint inside an electronic device casing according to the various implementations.

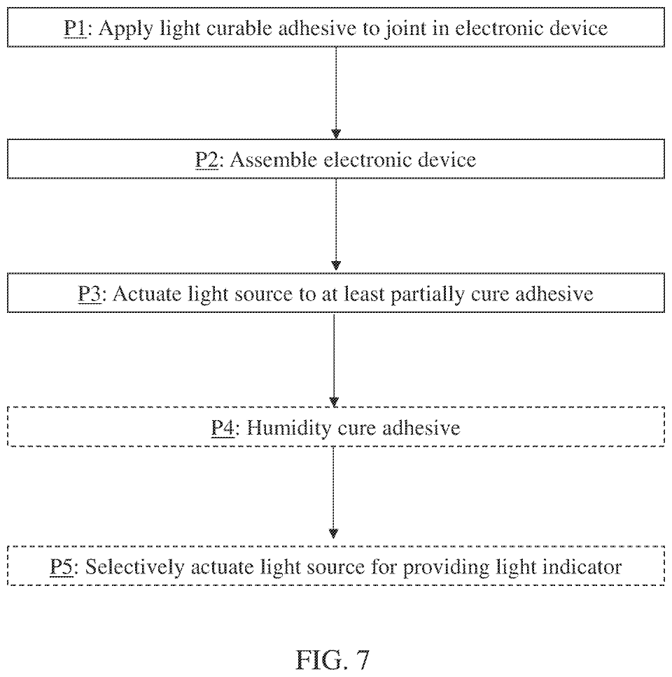

FIG. 7 is a flow diagram illustrating processes in a method of curing an adhesive (e.g., adhesive 70) in an electronic device (e.g., electronic device(s) 10, 10A, 10B, 10C etc.). In one example, with reference to FIG. 1, a first process (P1) includes applying a light curable adhesive (e.g., adhesive 70) to a joint (e.g., joint 60) in an electronic device (e.g., electronic device 10). In various implementations the adhesive 70 is flowed onto one or both components 50 and the components 50 are joined together. In additional cases, further adhesive is applied (e.g., flowed) into a space between components 50 where such a gap exits. In another process (P2), the electronic device 10 is assembled. For example, the casing 20 (e.g., outer casing) can be assembled such that access to internal components 50 is either limited or requires disassembly of the casing 20. In this sense, the adhesive 70 at the joint 60 is no longer visible from the exterior of the casing 20. In another process (P3), a light source (e.g., light source 80) is actuated to provide light with sufficient intensity to at least partially cure the adhesive 70 within the electronic device 10. As described herein, various approaches can be used to actuate a light source for curing (e.g., fixture curing) the light curable adhesive 70. In one example, a light source 80 that is internal to the electronic device 10 is actuated to cure the adhesive 70. In an additional process (P4), which can be performed at a later time (as indicated in phantom) the adhesive 70 is finally cured by exposure to humidity over time. That is, the light curing can partially cure adhesive 70 (establishing a fixture cure), and a full cure can be finished by humidity exposure over time. In a further (optional) process (P5) as indicated in phantom, the light source 80 can be selectively actuated for providing a light indicator at the electronic device 10. That is, the light source 80 can be selectively actuated in process P3 for curing the adhesive 70, and after the adhesive 70 is finally cured in process P5, the light source 80 can be selectively actuated to provide a light indicator at the electronic device 10 (e.g., as illustrated by light indicator 170 in FIGS. 1, 4, and 5).

As described herein, various implementations include exposing the joint 60 to light from the light source 80 prior to use, e.g., prior to packaging, shipping, sale and/or use by a consumer. In various implementations, the joint 60 is exposed to light from the light source 80 prior to testing of the electronic device 10. In certain examples, the adhesive 70 is exposed to light from the light source 80 within approximately several minutes to an hour after application of the adhesive 70 to the joint 60. In particular cases, the adhesive 70 is exposed to light from the light source 80 prior to a subsequent assembly process that would impart stress on the joint 60, e.g., in a matter of minutes. However, the adhesive 70 can be exposed to light from the light source 80 any time prior to the complete humidity cure, e.g., any time prior to approximately 48-72 hours after application of the adhesive 70.

In contrast to conventional electronic devices, the electronic devices (and approaches) described herein can provide for enhanced component bonding, particularly for bonds that are internal to the device and/or otherwise obstructed from external light. For example, audio devices such as speakers, audio eyeglasses, headphones and/or earphones (e.g., ear buds) can benefit from enhanced bonding of components that are subject to vibrational forces during use (e.g., by vibration caused by and/or reverberated by an electro-acoustic transducer, passive radiator, microphone, etc.). The electronic devices described herein can have enhanced performance when compared with conventional devices, for example, with fewer joint failures, longer joint life, and/or reduced vibration caused by joints. Additionally, the electronic devices described herein can be more easily manufactured than conventional devices requiring complicated joint geometries and/or construction in order to account for weaker bonding between components. That is, the ability to at least partially cure a light curable adhesive at locations inside an electronic device after assembly enables more efficient assembly of the device components when compared with conventional approaches.

One or more components in the electronic devices described herein can be formed of any conventional electronic device material, e.g., a heavy plastic, metal (e.g., aluminum, or alloys such as alloys of aluminum), composite material, etc. It is understood that the relative proportions, sizes and shapes of the transducer(s) and components and features thereof as shown in the FIGURES included herein can be merely illustrative of such physical attributes of these components. That is, these proportions, shapes and sizes can be modified according to various implementations to fit a variety of products.

In various implementations, components described as being “coupled” to one another can be joined along one or more interfaces. In some implementations, these interfaces can include junctions between distinct components, and in other cases, these interfaces can include a solidly and/or integrally formed interconnection. That is, in some cases, components that are “coupled” to one another can be simultaneously formed to define a single continuous member. However, in other implementations, these coupled components can be formed as separate members and be subsequently joined through known processes (e.g., soldering, fastening, ultrasonic welding, bonding).

A number of implementations have been described. Nevertheless, it will be understood that additional modifications may be made without departing from the scope of the inventive concepts described herein, and, accordingly, other implementations are within the scope of the following claims.

We claim:

1. An electronic device, comprising:
a casing defining an enclosure;
a joint between components in the electronic device;
an light curable adhesive bonding the components at the joint; and
at least one light source internal to the casing and configured to output light for at least partially curing the light curable adhesive in the casing.

2. The electronic device of claim 1, further comprising a light pipe proximate to the at least one light source for distributing the light to cure the light curable adhesive.

3. The electronic device of claim 1, wherein the casing is substantially opaque.

4. The electronic device of claim 3, wherein after the casing is assembled, the light curable adhesive is only exposed to light from the at least one light source.

5. The electronic device of claim 1, further comprising:
a printed circuit board (PCB) in the enclosure,
wherein the at least one light source is coupled with the PCB.

6. The electronic device of claim 5, wherein the at least one light source includes a light emitting diode (LED).

7. The electronic device of claim 6, further comprising a reflective mask on the PCB for diffusing the light.

8. The electronic device of claim 6, wherein the LED is mounted directly to the PCB.

9. The electronic device of claim 6, wherein the LED includes a multi-directional LED.

10. The electronic device of claim 6, wherein the PCB is configured to diffuse the light from the LED during curing of the light curable adhesive.

11. The electronic device of claim 1, further comprising a controller coupled with the at least one light source for selectively controlling the output of light for curing the light curable adhesive.

12. The electronic device of claim 11, wherein the at least one light source comprises a multi-wavelength light source, and wherein the controller is configured to:
actuate output of a first wavelength of light from the at least one light source for curing the light curable adhesive; and
actuate output of a second wavelength of light from the at least one light source for providing a light indicator at the electronic device,
wherein the first wavelength comprises a portion of the UV spectrum.

13. The electronic device of claim 12, wherein the controller is configured to output the first wavelength of light during assembly of the electronic device and output the second wavelength of light after assembly of the electronic device is complete.

14. The electronic device of claim 11, wherein the at least one light source comprises a multi-direction light source, and wherein the controller is configured to:
actuate output of light from the at least one light source in a first direction for curing the light curable adhesive; and
actuate output of light from the at least one light source in a second direction for providing a light indicator at the electronic device.

15. The electronic device of claim 1, further comprising an at least partially reflective coating within the enclosure for diffusing the light.

16. The electronic device of claim 1, wherein the at least one light source is powered by a device external to the casing.

17. The electronic device of claim 16, wherein the device external to the casing is configured to power the at least one light source by one or more of: inductive coupling, radio-frequency (RF) communication, trans-enclosure capacitive coupling, or hard-wired power extending through the casing.

18. The electronic device of claim 1, wherein the light curable adhesive is additionally cured with humidity exposure.

19. The electronic device of claim 1, wherein the casing is an outermost casing of the electronic device.

20. An audio device comprising the electronic device of claim 1.
